(19) United States
(12) Patent Application Publication
(10) Pub. No.: US 2025/0216450 A1
(43) Pub. Date: Jul. 3, 2025

(54) TEST DEVICE FOR OPTOELECTRONIC INTEGRATED CIRCUIT BEFORE BEING CO-PACKAGED

(71) Applicant: Chunghwa Precision Test Tech. Co., Ltd., Taoyuan City (TW)

(72) Inventors: Jhih-hong CHENG, Taoyuan City (TW); Jia-yu HSU, Taoyuan City (TW)

(73) Assignee: Chunghwa Precision Test Tech. Co., Ltd., Taoyuan City (TW)

(21) Appl. No.: 18/906,188

(22) Filed: Oct. 4, 2024

(30) Foreign Application Priority Data
Jan. 2, 2024 (TW) 113100135

(51) Int. Cl. G01R 31/28; G01R 31/265

(52) U.S. Cl. CPC G01R 31/2896; G01R 31/2656; G01R 31/2886

(57) ABSTRACT

A test device for an optoelectronic integrated circuit before being co-packaged includes a first jig, a first optical transmission assembly, a second optical transmission assembly, an interposer, a test load board, and a second jig. The first jig and the second jig are arranged up and down in a direction perpendicular to the test load board. A first photonic die and a second electronic integrated circuit are arranged in an accommodation space of the first jig. A first electronic integrated circuit is disposed in a groove portion of the second jig. A first signal transmission loop is formed between the test load board, the first electronic integrated circuit, the first photonic die, and the second photonic die. A second signal transmission loop is formed between the test load board, the first electronic integrated circuit, the interposer, and the second electronic integrated circuit.

### CROSS REFERENCE TO RELATED APPLICATIONS

This application claims the benefit of priority of Taiwan Patent Application No. 113100135, filed Jan. 2, 2024, the disclosure of which is incorporated herein by reference in its entirety.

### BACKGROUND OF INVENTION

### 1. Field of Invention

This application relates to a technical field of electrical testing, and particularly to a test device for an optoelectronic integrated circuit before being co-packaged.

### 2. Related Art

Optoelectronic integrated circuits (OEIC) include photonic integrated circuits and electronic integrated circuits, which use light for data transmission and are suitable for high-performance data exchange, long-distance interconnection, 5G facilities, and computing devices. Photonic integrated circuits and electronic integrated circuits are co-packaged to form co-packaged optics (CPO). Packaged semiconductor devices generally need to be tested to obtain various electrical characteristic parameters as a basis for good product screening. Once a semiconductor device is tested and found to have defects, it is considered a defective product and cannot enter the market. However, there is currently a lack of testing equipment for co-packaged optical components that can meet customized designs. In addition, co-packaged semiconductor devices that are detected to be defective may be due to the inability to generate an effective electrical circuit between electronic integrated circuits and photonic integrated circuits, but individual components function normally. In other words, defective products in a final test stage after co-packaged inevitably must be disassembled or taken back, which will undoubtedly lead to problems, such as high manufacturing costs and lower yields.

### SUMMARY OF INVENTION

An object of the present application is to provide a test device that is adapted for electrical characteristic testing of an optoelectronic integrated circuit with a stacked structure before being co-packaged, so as to solve problems of high manufacturing costs and low yields resulting from the issue that co-packaged products must be disassembled or taken back if defects are found in a final test stage.

Another object of the present application is to provide a test device that can meet testing needs of various types of photonic integrated circuits.

In order to achieve the above objects, the present application provides a test device for an optoelectronic integrated circuit before being co-packaged, the optoelectronic integrated circuit including a stack of a first photonic die and a first electronic integrated circuit. The test device is electrically connected to automatic test equipment and includes a first jig, including a first base, a cover plate, and a plurality of first conductor elements. The first base includes a first bottom plate and a first side wall, the cover plate covers a top of the first base and forms an accommodation space with the first bottom plate and the first side wall. The first photonic die is disposed in the accommodation space, and a plurality of through holes are positioned in the first bottom plate. A first optical transmission assembly includes a first end portion positioned in the accommodation space and close to the first photonic die. A second optical transmission assembly includes a second end portion positioned in the accommodation space and close to the first photonic die. The first optical transmission assembly and the second optical transmission assembly are configured to send a test light signal to the first photonic die or receive a light output signal generated by the first photonic die. An interposer is disposed on a side of the first bottom plate, and the first conductor elements are arranged at intervals and pass through corresponding via holes included in the interposer and the first bottom plate, and are electrically connected between the first photonic die and the first electronic integrated circuit. A test load board is electrically connected to the automatic test equipment. A second jig is disposed on the test load board and includes a second base and a plurality of first signal conductors. The second base includes a second bottom plate, a second side wall, and a groove portion, and the groove portion is located between the second side wall and the second bottom plate. The first jig and the second jig are arranged up and down in a direction perpendicular to the test load plate, the first electronic integrated circuit is disposed in the groove portion, and the first signal conductors pass through the second bottom plate and are electrically connected between the first electronic integrated circuit and the test load board.

Optionally, the optoelectronic integrated circuit further includes a second electronic integrated circuit, the first jig further includes a plurality of second signal conductors, and the second electronic integrated circuit is arranged on the interposer and located in the accommodation space. The second signal conductors are arranged at intervals and pass through the corresponding through holes of the first bottom plate, and are electrically connected between the interposer and the first electronic integrated circuit.

Optionally, the optoelectronic integrated circuit further includes a second photonic die, the first jig further includes a plurality of second conductor elements, and the test device further includes another first optical transmission assembly and another second optical transmission assembly. the second photonic die is disposed in the accommodation space, the another first optical transmission assembly and the another second optical transmission assemblies are disposed in the accommodation space and close to the second photonic die, respectively. The second conductor elements are arranged at intervals and pass through the corresponding via holes of the interposer and the first bottom plate and are electrically connected between the second photonic die and the first electronic integrated circuit.

Optionally, the first jig further includes a retaining element disposed on a side of the first side wall or the cover plate, and the first photonic die and/or the second photonic die are fixed on the retaining element and suspended in the accommodation space.

Optionally, the first jig further includes a first elastic buffer element, which is disposed on a side of the cover plate and pressed against the first photonic die and the second photonic die.

Optionally, the first jig further includes a first elastic buffer element, which is disposed on a side of the cover plate and pressed against the first photonic die and the second electronic integrated circuit.

Optionally, the first jig further includes a second elastic buffer element, which is disposed on a side of the interposer and is pressed against the first electronic integrated circuit.

Optionally, the test device further includes a first connecting member and a second connecting member, and the first connecting member is detachably connected to the second connecting member to connect and fix the first jig and the second jig to the test load board.

Optionally, the first electronic integrated circuit includes a first packaging structure, and the second electronic integrated circuit includes a second packaging structure.

Optionally, the first side wall is arranged around the first bottom plate and the accommodation space, and the first optical transmission assembly further includes a first optical fiber, a first plug, and a first connector. The first connector is disposed on the first side wall, the first optical fiber comprises the first end portion, and the first plug is fixed on the first end portion and pluggably connected to the first connector.

Optionally, the first photonic die includes a first optical waveguide, the first optical fiber is aligned with the first optical waveguide, and the first end portion is disposed close to the first optical waveguide.

Optionally, the first photonic die includes a first optical waveguide, and the first connector of the first optical transmission assembly includes an optical channel and a reflective wall. The reflective wall is located at an acute angle with respect to the first optical fiber and the first photonic die, the test light signal is reflected to the first optical waveguide through the reflective wall, or the light output signal is reflected through the reflective wall to the first end portion.

Optionally, the first photonic die includes a first optical waveguide, the first connector of the first optical transmission assembly includes an optical channel, and the cover plate includes a slot including an inclined portion. The inclined portion includes a reflective material with a reflection coefficient greater than that of air and is located at an acute angle with respect to the first optical fiber and the first bottom plate, a part of the first connector is embedded in the slot, and the optical channel extends to the inclined portion. The test light signal is reflected to the first optical waveguide through the inclined portion, or the light output signal is reflected to the first end portion through the inclined portion.

Optionally, the first photonic die includes a second optical waveguide, and the second optical transmission assembly comprises a second optical fiber, a second plug, and a second connector, and the second optical fiber includes the second end portion, The second connector is obliquely embedded in the cover plate, the second plug is fixed to the second end portion and is pluggably connected to the second connector, and the second end portion is located above the second optical waveguide.

Optionally, the test device further includes a third optical transmission assembly comprising a third optical fiber, a third plug, a third connector, and an interconnecting optical fiber. The third connector is embedded in the first bottom plate, the third optical fiber includes a third end portion, the third plug is fixed to the third end portion and is pluggably connected to the third connector, one end of the interconnecting optical fiber is connected to the third connector, and the other end is connected to the first photonic die.

After the first photonic die, the second photonic die, the first electronic integrated circuit, the second electronic integrated circuit, and the interposer are successfully tested by the test device of this application and the automatic test equipment, they can be assured to be non-defective prior to co-packaged and after the chip probe test stage, so they can be formed into co-packaged optics with a stacked structure in a single package through co-packaging technology, which in turn effectively solves problems of high manufacturing costs and low yields resulting from the issue that the photonic integrated circuit and the electronic integrated circuit after being co-packaged must be disassembled or taken back if defects are found in a final test stage.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a schematic structural view of a test device for an optoelectronic integrated circuit before being co-packaged according to an embodiment of the present application.

FIG. 2 is a schematic structural view of a test device according to another embodiment of the present application.

FIG. 3 is a schematic structural view of a test device according to another embodiment of the present application.

FIG. 4 is a schematic structural view of a test device according to another embodiment of the present application.

FIG. 5 is a schematic enlarged view of a partial structure of a test device according to one embodiment of the present application.

FIG. 6 is a schematic enlarged view of a partial structure of a test device according to one embodiment of the present application.

FIG. 7 is a schematic enlarged view of a partial structure of a test device according to one embodiment of the present application.

FIG. 8 is a schematic enlarged view of a partial structure of a test device according to one embodiment of the present application.

FIG. 9 is a schematic enlarged view of a partial structure of a test device according to one embodiment of the present application.

FIG. 10 is a schematic enlarged view of a partial structure of a test device according to one embodiment of the present application.

FIG. 11 is a schematic enlarged view of a partial structure of a test device according to one embodiment of the present application.

### DESCRIPTION OF PREFERRED EMBODIMENTS

The following is a detailed description of the embodiments in conjunction with the accompanying drawings. The specific embodiments described are only used to explain the invention and are not used to limit the invention. The description of the structural operations is not intended to limit the order of its execution. Any structures recombined with components to produce devices with equal functions are within the scope of the disclosure of the present invention.

It should be noted that in the corresponding drawings of the embodiments, lines are used to represent signals. Some lines may be thicker to indicate more components of signal paths, and/or some lines may have arrows at one or more ends to indicate the main direction of information flow. This indication is not intended to be restrictive. Rather, lines are used in connection with one or more exemplary embodiments for ease of understanding of circuits or logic elements. Any represented signal may actually include one or more signals that may travel in either direction, as specified by design requirements or preferences, and may be implemented using any suitable type of signaling scheme.

In the text below and in the claims, the term “coupled” and its derivatives may be used. The term “coupled” herein refers to two or more elements that are in direct contact (physically, electrically, magnetically, optically, etc.). The term “coupled” may also be used herein to refer to two or more elements that are not in direct contact with each other, but still cooperate or interact with each other.

As used herein, unless otherwise stated, the ordinal adjectives “first,” “second,” “third,” etc., used herein to describe common objects, merely indicate the different aspects of the similar objects being mentioned.

Examples are not intended to imply that the objects so described must be in a given order in time, space, arrangement or in any other manner.

The present application provides a test device for testing electrical characteristics of an optoelectronic integrated circuit before being co-packaged. In some embodiments, the optoelectronic integrated circuit is an electronic integrated circuit (EIC) including an electrical computing processor and a photonic integrated circuit (PIC) responsible for electro-optical conversion. According to the test device provided by this application, after testing, the optoelectronic integrated circuit can use 2.5D packaging technology or 3D packaging technology according to actual design requirements to integrate the electronic integrated circuit and the photonic integrated circuit into a single packaging structure, and form a stacked structural co-packaged optics (CPO). In other words, the test device disclosed in the present application is designed based on co-packaged optics with a stacked structure. It should be noted that the photonic integrated circuit to be tested may include at least a light detection element and a light source module, as well as a plurality of active components and passive components, such as but not limited to filters or multiplex structures, optical power distribution structures, fiber input and output structures, and light modulation structures. Since the present application is not characterized by the detailed structures of optical active and passive components known to those skilled in the art, they will not be described in detail here.

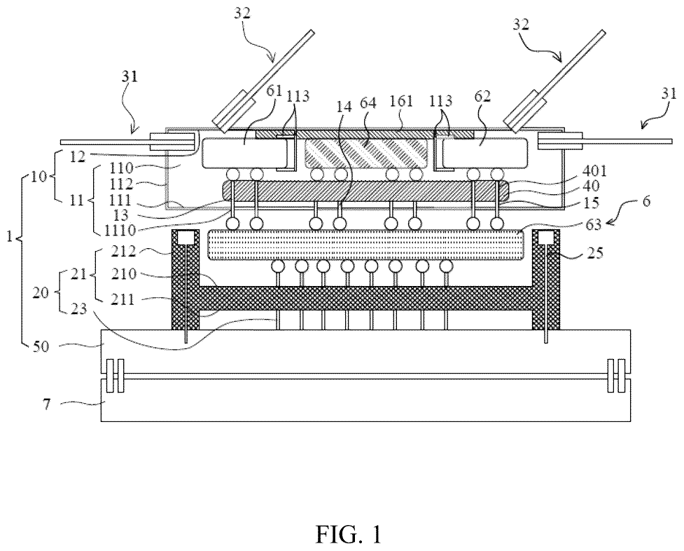

Referring to FIG. 1, FIG. 1 is a schematic structural view of a test device for an optoelectronic integrated circuit before being co-packaged according to an embodiment of the present application. The embodiment of the present application provides a test device 1 including a first jig 10, a second jig 20, a first optical transmission assembly 31, a second optical transmission assembly 32, an interposer 40, and a test load board 50. The test device 1 in the embodiment of the present application is electrically connected to an automatic test equipment (ATE) 7, and is used for electrical characteristic testing of an optoelectronic integrated circuit 6 before being co-packaged. In some embodiments, the optoelectronic integrated circuit 6 as a device under test includes a first photonic die 61, a second photonic die 62, a first electronic integrated circuit 63, and a second electronic integrated circuit 64. Preferably, the above-mentioned electrical characteristic testing includes items, for example, voltage, current, resistance, reverse leakage, voltage-current relationship, and electric circuits between the first photonic die 61, the second photonic die 62, the first electronic integrated circuit 63, and the second electronic integrated circuit 64, but is not limited thereto.

In some embodiments, the first electronic integrated circuit 63 may be a system on chip (SOC) including a plurality of processing units with different functions integrated and packaged together, and the second electronic integrated circuit 64 may be a memory, such as a dynamic random access memory or other volatile memory, but is not limited to the above. In some embodiments, the first photonic die 61 and the second photonic die 62 are manufactured using a silicon on insulator (SOI) wafer to form the silicon photonic die. It should be noted that the photonic integrated circuit (i.e., the first photonic die 61 and the second photonic die 62) tested by the test device 1 may include at least a light detection element for converting optical signals into electrical signals, a light source module for converting electrical signals into optical signals, and a plurality of active components and passive components, such as but not limited to filters or multiplex structures, optical power distribution structures, optical fiber input and output structures, and optical modulation structures. Since the present application is not characterized by the detailed structure of optical active and passive components known to those skilled in the art, they will not be described in detail here.

As shown in FIG. 1, the first jig 10 includes a first base 11, a cover plate 12, a plurality of first conductor elements 13, a plurality of second signal conductors 14, and a plurality of second conductor elements 15. In some embodiments, the first base 11 has a substantially rectangular cross-section and includes a first bottom plate 111 and a first side wall 112, and the first side wall 112 is disposed around the first bottom plate 111. The cover plate 12 can be attached to cover a top of the first base 11, and form an accommodation space 110 together with the first bottom plate 111 and the first side wall 112. The accommodation space 110 is large enough to accommodate the first photonic die 61, the second photonic die 62, the second electronic integrated circuit 64, and the interposer 40 at the same time. It should be noted that a depth of the accommodation space 110 is greater than a height of the first photonic die 61 or the second photonic die 62 each staked with the interposer 40, or greater than a height of one or more second electronic integrated circuits 64 and the interposer 40 stacked. Preferably, the first bottom plate 111 is provided with a plurality of through holes 1110 arranged at intervals, and the through holes 1110 pass through the first bottom plate 111 to communicate with the accommodation space 110.

Still referring to FIG. 1, the interposer 40 is disposed on one side of the first bottom plate 111 and is located in the accommodation space 110. In this embodiment, the interposer 40 is a circuit board and includes a plurality of via holes 401. It should be noted that the configuration of some of the through holes 1110 of the first bottom plate 111 is designed according to the configuration of the via holes 401 of the interposer 40, so that the first conductor elements 13 pass through the corresponding through holes 1110 of the first bottom plate 111 and the via holes 401 of the interposer 40 and extend to the accommodation space 110 to electrically connect to the first photonic die 61. As shown in FIG. 1, the second conductor elements 15 pass through the corresponding through holes 1110 of the first bottom plate 111 and the corresponding via holes 401 of the interposer 40, respectively, and extend to the accommodation space 110 to electrically connect to the second photonic die 62. In other embodiments, the interposer 40 may not be provided with the via holes 401, but may include bump array contacts on a lower surface of the interposer 40 to communicate with the first conductor elements 13 and/or the second conductor elements 15 to make electrical contact, and other bump array contacts are disposed on an upper surface of the interposer 40 to make electrical contact with the photonic integrated circuit.

It should be noted that some of the first conductor elements 13 and some of the second conductor elements 15 serve as power conductors of the photonic integrated circuit. Specifically, the power required for the operation of specific components of the first photonic die 61 and the second photonic die 62, such as the light modulation structure or the light source module, is transmitted from the test load board 50 through the first electronic integrated circuit 63 to the first photonic die 61 and the second photonic die 62, respectively. Through the above structure, during photoelectric testing of the photonic integrated circuit, optical signals of the first optical transmission assembly 31 and the second optical transmission assembly 32 undergo a photoelectric conversion process through the first photonic die 61 and the second photonic die 62, then signals being converted are transmitted from predetermined first conductor elements 13 and predetermined second conductor elements 15 for testing.

As shown in FIG. 1, the second electronic integrated circuit 64 is arranged on the interposer 40 and located in the accommodation space 110, and the first photonic die 61 and the second photonic die 62 are arranged around the second electronic integrated circuit 64. Preferably, the upper surface of the interposer 40 has bump array contacts to electrically connect to the second electronic integrated circuit 64. The second signal conductors 14 are spaced apart and pass through the corresponding through holes 1110 of the first bottom plate 111, and are electrically connected between the interposer 40 and the first electronic integrated circuit 63, so that signals are transmitted between the second electronic integrated circuit 64 and the integrated circuits 63. In some embodiments, the first conductor elements 13, the second signal conductors 14, and the second conductor elements 15 can be extremely short needles or high-speed probes, or coaxial spring probes, which can be configured according to actual testing requirements. Since the present application is not characterized by the detailed structure of probes known to those skilled in the art, it will not be described in detail here.

Still referring to FIG. 1, the first jig 10 further includes two retaining elements 113 arranged corresponding to the number of photonic integrated circuits to be tested, and are configured to hold the first photonic die 61 and the second photonic die 62 in the accommodation space 110. In some embodiments, the retaining elements 113 may be disposed on the first side wall 112 and are configured with an embedded structure, so that the first photonic die 61 and the second photonic die 62 are embedded and retained in the retaining elements 113, respectively. In other embodiments, the retaining elements 113 can be disposed on a side of the cover plate 12 facing the accommodation space 110, and are configured with an embedded structure for retaining the first photonic die 61 and the second photonic die 62. That is, the first photonic die 61 and the second photonic die 62 are not fixed on the interposer 40, but are suspended in the accommodation space 110.

In some embodiments, the first jig 10 further includes a first elastic buffer element 161, which is made of a material with elastic and deformable properties, such as elastic polymer, rubber, silicone, etc. Preferably, the first elastic buffering element 161 is disposed on a side of the cover plate 12 and is pressed toward the interposer 40 to further fix the first photonic die 61, the second photonic die 62, and the second electronic circuit 64 to ensure that a device under test will not move during the test so that a test result will not be affected.

Still referring to FIG. 1, the second jig 20 is detachably disposed on the test load board 50, which is electrically connected to the automatic test equipment 7. In some embodiments, the second jig 20 includes a second base 21, a groove portion 210, and a plurality of first signal conductors 23. Specifically, the second base 21 has a substantially rectangular cross-section and includes a second bottom plate 211, and a second side wall 212 arranged around the second bottom plate 211. The groove portion 210 is formed between the second side wall 212 and the second bottom plate 211. The first electronic integrated circuit 63 is detachably disposed in the groove portion 210. In some embodiments, the second jig 20 further includes a holding structure (not shown) for holding the first electronic integrated circuit 63. The holding structure can be disposed on the second side wall 212 or the second bottom plate 211, and protrudes toward an inside of the groove portion 210 to hold the first electronic integrated circuit 63. As shown in FIG. 1, one end of each of the first signal conductors 23 is connected to the test load board 50, and the other end passes through the second bottom plate 211 and is electrically connected to the first electronic integrated circuit 63. In addition, the first photonic die 61 transmits optical signals through the first optical transmission assembly 31 and the second optical transmission assembly 32. Similarly, another first optical transmission assembly 31 and another second optical transmission assembly 32 are disposed in the accommodation space 110 and close to the second photonic die 62, respectively, for optical signal transmission with the second photonic die 62. A method and structure used in this application to implement the optical signal transmission will be described in detail in the following paragraphs.

Still referring to FIG. 1, the first jig 10 and the second jig 20 are arranged up and down in a direction perpendicular to the test load board 50. In some embodiments, the first jig 10 can be positioned above the second jig 20 through an external suspension mechanism (not shown), or can be directly stacked on the second jig 20, and the second jig 20 can be fixed on the test load plate 50 through a fixing member 25. During a testing process of the test device 1 of the present application, the first photonic die 61 and the second photonic die 62 are configured to perform optical signal transmission of light to electricity and electricity to light through the first optical transmission assembly 31 and the second optical transmission assembly 32. Specifically, a first signal transmission loop is formed between the test load board 50 and the first electronic integrated circuit 63 and the first photonic die 61/second photonic die 62. A second signal transmission loop is formed between the test load board 50, the first electronic integrated circuit 63, the interposer 40, and the second electronic integrated circuit 64, so that the automatic test equipment 7, through the test device 1, can perform electrical characteristic testing on an optoelectronic integrated circuit composed of the photonic integrated circuit and the electronic integrated circuit.

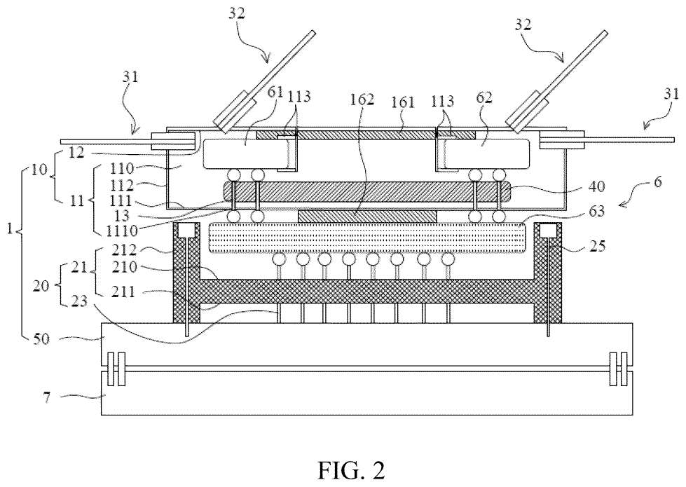

Referring to FIG. 2, FIG. 2 is a schematic structural view of a test device 1 according to another embodiment of the present application. The test device 1 in the embodiment of the present application can also test only the signal transmission between the photonic integrated circuit and the first electronic integrated circuit 63. As shown in FIG. 2, only the first photonic die 61 and the second photonic die 62 are provided in the first jig 10, and the second electronic integrated circuit 64 is not disposed on the interposer 40. That is, the test device 1 of this embodiment only tests the signal transmission between the first photonic die 61, the second photonic die 62 and the first electronic integrated circuit 63. Specifically, in the embodiment shown in FIG. 2, the first jig 10 further includes a second elastic buffer element 162, which is disposed on a side of the first bottom plate 111 facing the first electronic integrated circuit 63 and is pressed against the first electronic integrated circuit 63 thus ensuring that the first electronic integrated circuit 63 will not move.

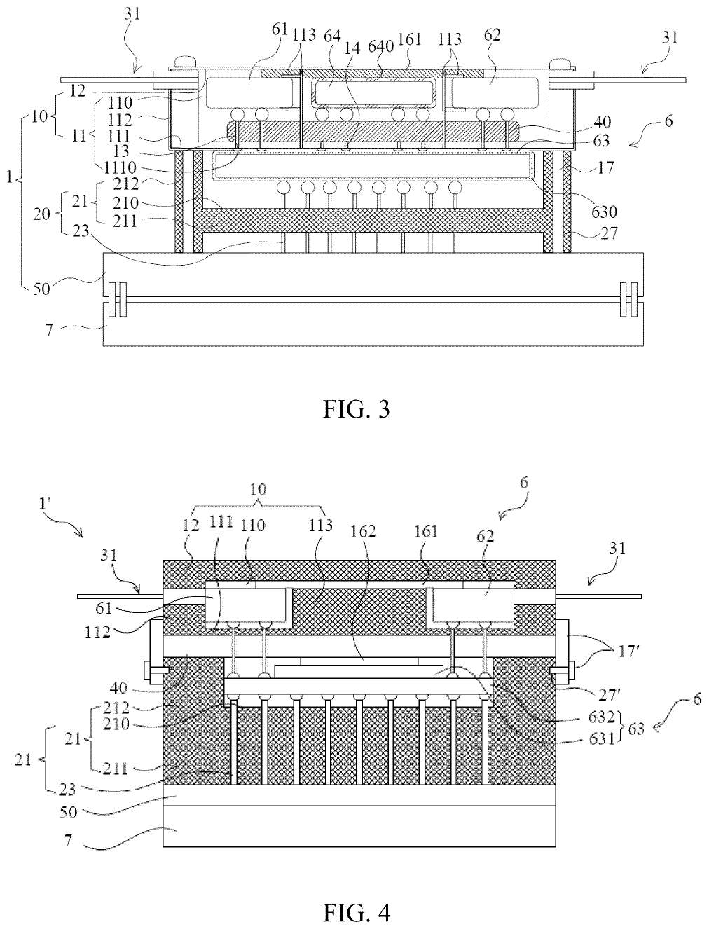

Referring to FIG. 3, FIG. 3 is a schematic structural view of a test device 1 according to another embodiment of the present application. In the test device 1 shown in FIG. 3, the first jig 10 is directly stacked on the second side wall 212 of the second jig 20, and the test device 1 further includes a first connecting member 17 and a second connecting member 27, and the first connecting member 17 is detachably connected to the second connecting member 27. In some embodiments, the first connecting member 17 and the second connecting member 27 can be a locking structure; preferably, the first connecting member 17 can be a locking nail, and the second connecting member 27 can be a thread formed in the second side wall 212 of the second base 21. The locking nail penetrates the first side wall 112 and is locked in the thread to connect and fix the first jig 10 and the second jig 20 to the test load board 50. It should be noted that the connection structure of the first connecting member 17 and the second connecting member 27 is not limited to the above. In addition, as shown in FIG. 3, the first electronic integrated circuit 63 includes a first packaging structure 630, and the second electronic integrated circuit 64 includes a second packaging structure 640. In other words, the first electronic integrated circuit 63 and the second electronic integrated circuit 64 tested in the embodiment of the present application are packaged chips, while the first photonic die 61 and the second photonic die 62 have not yet been packaged.

Referring to FIG. 4, FIG. 4 is a schematic structural view of a test device 1′ according to another embodiment of the present application. The main difference between the test device 1′ shown in FIG. 4 and the test device 1 shown in FIG. 1 is that the test device 1′ of FIG. 4 only tests the signal transmission between the photonic integrated circuit and the first electronic integrated circuit 63, and the interposer 40 is disposed outside the first bottom plate 111 of the first base 11 not in the accommodation space 110. Other structures that are the same as those of the test device 1 in FIG. 1 will not be described in detail here. As shown in FIG. 4, the interposer 40 is disposed on a side of the first bottom plate 111 facing the second base 21, and is sandwiched between the first base 11 and the second base 21 and located adjacent to the groove portion 210 of the second jig 20. A first electronic integrated circuit 63 being packaged and composed of a first die 631 and a first substrate 632 is disposed in the groove portion 210. In this embodiment, the test device 1′ further includes a first connecting member 17′ and a second connecting member 27′, which may be locking structures for connecting and fixing the first jig 10 to the second jig 20. In some embodiments, a second elastic buffer element 162 may be disposed on a bottom of the interposer 40 to be pressed against and fix the first electronic integrated circuit 63 below.

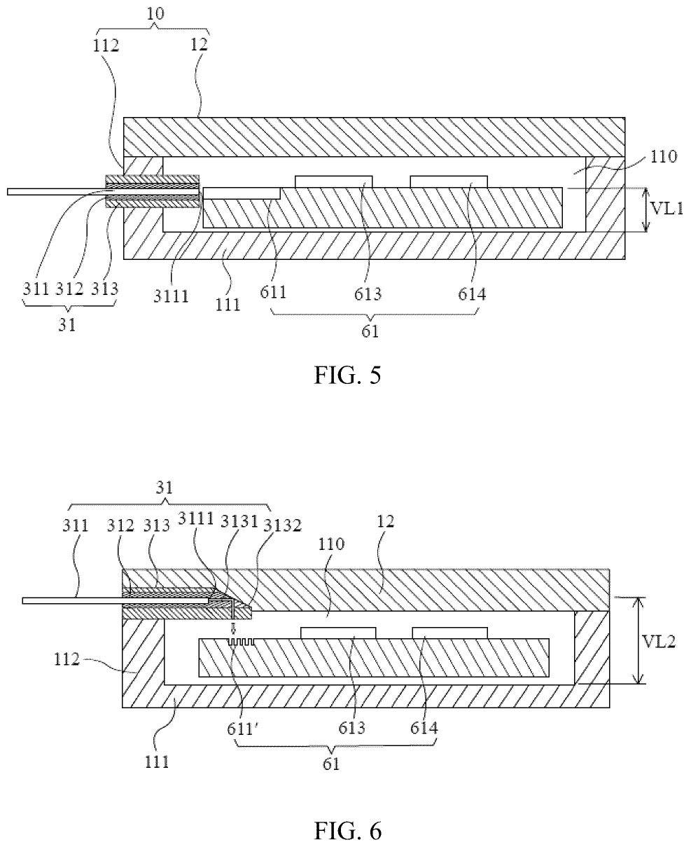

Referring to FIGS. 5 to 11, FIGS. 5 to 11 are schematic enlarged views of a partial structure of the test device according to different embodiments of the present application, which illustrates in detail the structure of the light transmission assembly used for the first photonic die 61 and the second photonic die 62. It should be noted that FIGS. 5 to 11 are mainly used to illustrate the structural relationship between photonic integrated circuits and optical transmission assemblies. Therefore, for the sake of clarity, the interposer 40, the first conductor elements 13, the via holes 401, and other components corresponding to the test device 1 of FIG. 1 are omitted from FIGS. 5 to 11. The optical transmission assembly in the embodiment of the present application uses an optical fiber as a medium to transmit optical signals. In some embodiments, the optical fiber can be a single-mode optical fiber, a polarization-maintaining optical fiber, or a lens optical fiber, but is not limited to the type of the aforementioned optical fiber. A main wavelength transmitted by this fiber is in a range of 1100 nanometers (nm) to 2000 nm. Preferably, the infrared light has a wavelength of 1550 nm. In addition, working principles of the optical transmission assemblies used for the first photonic die 61 and the second photonic die 62 are the same. Therefore, FIGS. 5 to 11 only illustrate the optical signal transmission between the first optical transmission assembly 31 and the second optical transmission assembly 32 and the first photonic die 61 for explanation.

As shown in FIG. 5, the first optical transmission assembly 31 includes a first optical fiber 311, a first plug 312, and a first connector 313. Specifically, the first optical fiber 311 includes a first end portion 3111, which is disposed in the accommodation space 110 and close to the first photonic die 61, the first connector 313 is disposed on the first side wall 112, and the first plug 312 is fixed on the first end portion 3111 and pluggably connected to the first connector 313. Preferably, the first end portion 3111 is located at a first vertical level VL1 with respect to the first bottom plate 111. In some embodiments, the first connector 312 can be made of metal or ceramic materials and has a structure such as a ferrule to provide good protection for the first optical fiber 311, thus preventing signal transmission from being affected by external factors. In other embodiments, the first connector 312 may have a V-groove grating structure so that a plurality of the first optical fibers 311 are arranged in an optical fiber array to reduce signal losses in optical coupling alignment of optical waveguide structures. As shown in FIG. 5, the first photonic die 61 includes a first optical waveguide 611, a light detection element 613, and a light source module 614. Preferably, the first optical waveguide 611 is made of a material with a refractive index greater than that of air, such as a polymer material of silicon, silicon oxide, silicon nitride, or silicon oxynitride, but is not limited thereto. The light detection element 613 is configured to convert an optical signal transmitted by the optical waveguide 611 into an electrical signal, and the light source module 614 is configured to convert the electrical signal into an optical signal to be emitted. In this embodiment, the first optical fiber 311 is aligned with the first optical waveguide 611, and the first end portion 3111 is located directly adjacent to the first optical waveguide 611. Specifically, the first optical fiber 311 is configured to transmit a test light signal, which is emitted directly from the first end portion 3111 to the first optical waveguide 611, so that the test light signal is transmitted to the light detection element 613 of the first photonic die 61 through the first optical waveguide 611.

Referring to FIG. 6, in this embodiment, the first connector 313 of the first optical transmission assembly 31 includes an optical channel 3131 and a reflective wall 3132, wherein the reflective wall 3132 is located at an acute angle with respect to the first optical fiber 311 and the first photonic die 61. In this embodiment, the first end portion 3111 is located at a second vertical level VL2 with respect to the first bottom plate 111, and a height of the second vertical level VL2 is greater than a height of the first vertical level VL1. As shown in FIG. 6, the first photonic die 61 includes a first optical waveguide 611′ with a grating structure. Specifically, the grating structure includes a plurality of V-shaped grooves (not shown) arranged side by side in rows, so that a plurality of the first optical fibers 311 are arranged in an optical fiber array to reduce signal losses in optical coupling alignment of optical waveguide structures. The test light signal transmitted by the first optical fiber 311 is reflected to the reflective wall 3132 through the optical channel 3131, and is reflected from the cover plate 12 in a downward direction to the first optical waveguide 611′, and finally transmitted to the light detection element 613.

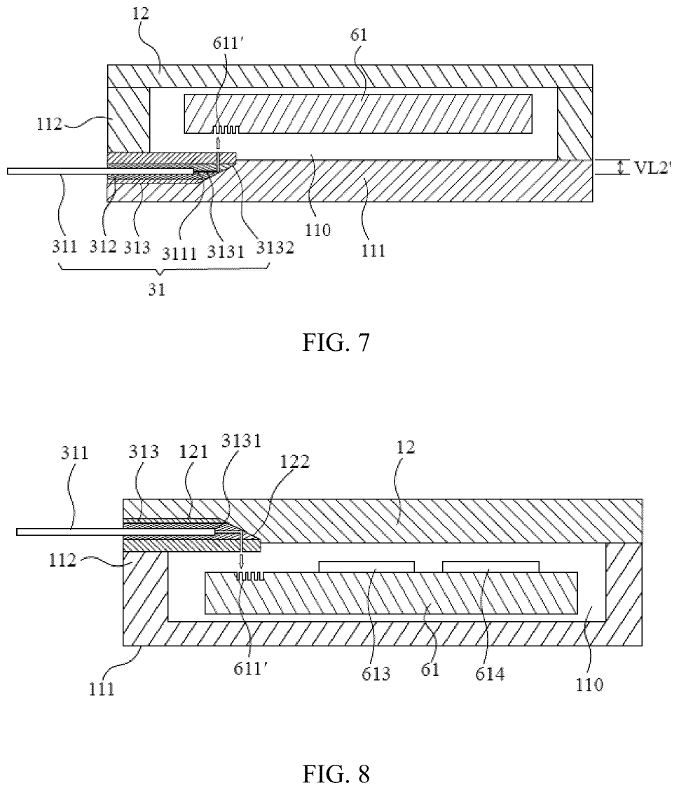

Referring to FIG. 7, the structure of the first optical transmission assembly 31 shown in FIG. 7 is substantially the same as that of the first optical transmission assembly 31 shown in FIG. 6, but the first optical transmission component 31 shown in FIG. 7 is located below the first photonic die 61. In detail, as shown in FIG. 7, the first connector 313 of the first optical transmission assembly 31 includes an optical channel 3131 and a reflective wall 3132. Specifically, the reflective wall 3132 is located at an acute angle with respect to the optical fiber 313 and the first photonic die 61. In this embodiment, the first end portion 3111 is located at a second vertical level VL2′ with respect to the first bottom plate 111, and a height of the second vertical level VL2′ is less than a height of the first vertical level VL1. As shown in FIG. 7, a first optical waveguide 611′ having a grating structure is formed on a lower surface of the first photonic die 61. The test light signal transmitted by the first optical fiber 311 is reflected by the reflective wall 3132 and reflected upward in a lower direction of the first photonic die 61 to the first optical waveguide 611′.

Referring to FIG. 8, a first photonic die 61 includes a first optical waveguide 611′, a first connector 313 of a first optical transmission assembly 31 includes an optical channel 3131, and a cover plate 12 includes a slot 121 including an inclined portion 122. In detail, the inclined portion 122 of the cover plate 12 includes a reflective material and is located at an acute angle with the first optical fiber 311 and the first bottom plate 111, and a part of the first connector 313 is embedded in the slot 121, and the optical channel 3131 extends to the inclined portion 122. The test light signal transmitted by the first optical fiber 311 passes through the optical channel 3131 and is reflected to the first optical waveguide 611′ via the inclined portion 122, and is finally transmitted to the light detection element 613.

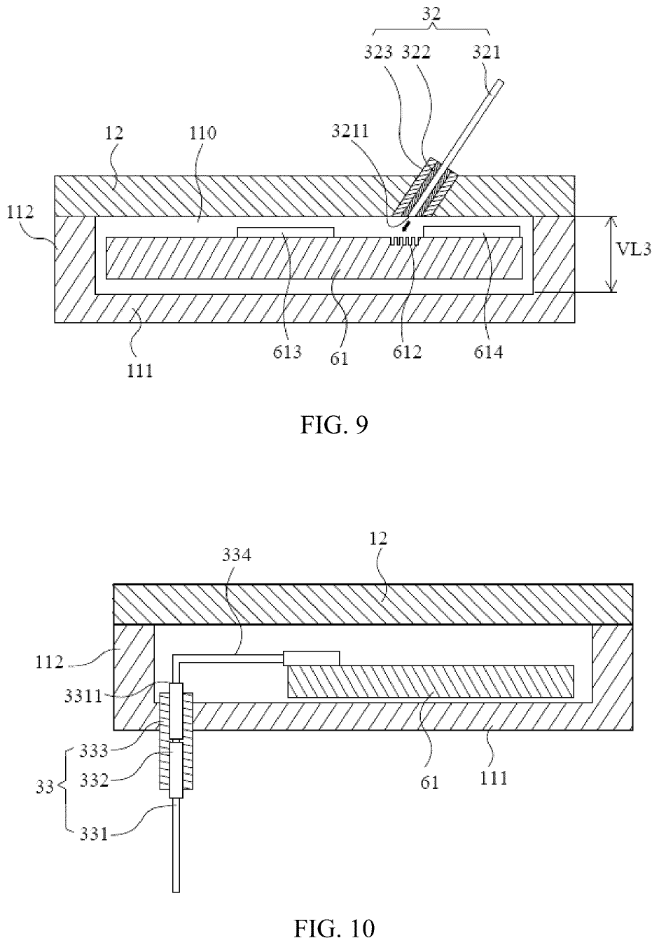

Referring to FIG. 9, the second optical transmission assembly 32 includes a second optical fiber 321, a second plug 322, and a second connector 323, and the second optical fiber 321 includes a second end portion 3211. In detail, the second connector 323 is obliquely embedded in the cover plate 12, and the second plug 322 is fixed on the second end portion 3211 and is pluggably connected to the second connector 323. In this embodiment, the first photonic die 61 includes a second optical waveguide 612, and the second end portion 3211 of the second optical fiber 321 is disposed above the second optical waveguide 612 and located at a third vertical level VL3 with respect to the first bottom plate 111. A height of the third vertical level VL3 is different from the height of the first vertical level VL1 or the second vertical level VL2. It should be noted that the angle of the second connector 323 relative to the first photonic die 61 depends on the design of the second optical waveguide 612. As shown in FIG. 9, the second optical fiber 321 is configured to transmit a test light signal, and the test light signal is emitted directly from a top of the first photonic die 61 to the second optical waveguide 612 and is detected by the light detection element 613.

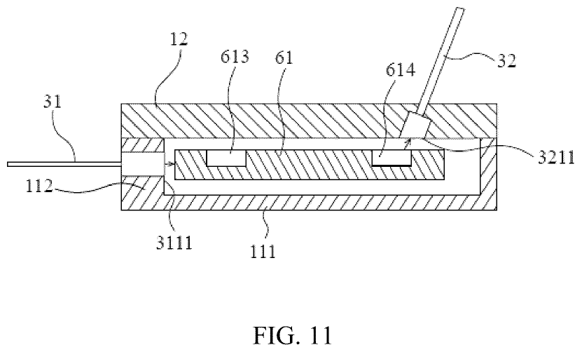

Referring to FIG. 10, in some embodiments, the test device 1 further includes a third optical transmission assembly 33, which includes a third optical fiber 331, a third plug 332, a third connector 333, and an interconnecting optical fiber 334, and the third optical fiber 331 includes a third end portion 3311. In detail, the third connector 333 is embedded in the first bottom plate 111, and the third plug 332 is fixed on the third end portion 3311 and is pluggably connected to the third connector 333. As shown in FIG. 10, one end of the interconnecting optical fiber 334 is connected to the third connector 333, and the other end is connected to the first photonic die 61. By means of the above structure, the third optical fiber 331 transmits a test light signal to the first photonic die 61 through the interconnecting optical fiber 334. It should be noted that FIGS. 5 to 10 only show that a single optical transmission assembly transmits the test light signal for being detected by the light detection element 613 of the first photonic die 61. For the sake of clarity, another optical transmission assembly for receiving the light signal emitted by the light source module 614 is omitted.

Referring to FIG. 11, FIG. 11 is a schematic enlarged view of the partial structure of the test device according to one embodiment of the present application. In this embodiment, the first optical transmission assembly 31 is disposed on the first side wall 112 to transmit a test light signal, and the test light signal is converted into an electrical signal through the light detection element 613. The second optical transmission assembly 32 is disposed on the cover plate 12 and is used for transmitting a light signal converted from the electrical signal through the light source module 614. In this embodiment, the test light signal is transmitted in a horizontal direction relative to the first photonic die 61, and an outgoing light signal is transmitted toward the second optical transmission assembly 32 above the first photonic die 61 to realize a test type in which a light input signal (i.e., the test light signal) and a light output signal are transmitted in different directions. In other embodiments, the test light signal and the light output signal are transmitted in the same direction (not shown). It should be noted that the positions of transmitting the test light signal and the light output signal mainly depend on the light detection element 613 and the light source module 614 of the first photonic die 61, thereby realizing different test types for various designs of photonic integrated circuits to be tested.

A variety of optical coupling types in different directions are formed through the cooperation of the first optical transmission assembly 31, the second optical transmission assembly 32, and/or the third optical transmission assembly 33 located at different vertical levels, thereby enabling electrical testing of different photonic integrated circuit designs. In particular, according to the design of the optoelectronic integrated circuit, each side of the test device 1 of the present application can be provided with a plurality of the optical transmission assemblies mentioned in the above embodiments to improve signal transmission efficiency.

The test device provided in this application utilizes the cooperation of the optical transmission assemblies, the first jig, the interposer, the second jig, and the test load board to enable the electrical characteristic testing to be performed through the automatic test equipment on the photonic integrated circuit and the electronic integrated circuit before being co-packaged. After testing, the first photonic die, the second photonic die, the first electronic integrated circuit, the second electronic integrated circuit, and the interposer can be formed into co-packaged optics with a stacked structure in a single package through co-packaging technology. By means of the test device of this application, the optoelectronic integrated circuit is allowed to be tested after a chip prob test stage and before a final test stage taking place after co-packaged, which in turn effectively solves problems of high manufacturing costs and low yields resulting from the issue that the photonic integrated circuit and the electronic integrated circuit after being co-packaged must be disassembled or taken back if defects are found in a final test stage.

Reference in the specification to “embodiments,” “one embodiment,” “some embodiments,” or “other embodiments” means that a particular feature, structure, or characteristic described in connection with the embodiment is included in at least some embodiments. However, it is not necessarily included in all embodiments. The various appearances of “embodiment,” “one embodiment,” or “some embodiments” are not necessarily all referring to the same embodiment. If the specification states that an element, feature, structure, or characteristic “may,” “could”, or “can” be included, that particular element, feature, structure, or characteristic need not be included. If the specification or claims refer to “a” or “an” element, this does not mean there is only one of the element. If the specification or claims refer to “another” element, this does not exclude the presence of more than one additional element.

Accordingly, although the present invention has been disclosed as a preferred embodiment, it is not intended to limit the present invention. Those skilled in the art without departing from the scope of the present invention may make various changes or modifications, and thus the scope of the present invention should be after the appended claims and their equivalents.

What is claimed is:

1. A test device for an optoelectronic integrated circuit before being co-packaged, the optoelectronic integrated circuit comprising a stack of a first photonic die and a first electronic integrated circuit, and the test device electrically connected to automatic test equipment and comprising:
a first jig comprising a first base, a cover plate, and a plurality of first conductor elements, wherein the first base comprises a first bottom plate and a first side wall, the cover plate covers a top of the first base and forms an accommodation space with the first bottom plate and the first side wall, the first photonic die is disposed in the accommodation space, and a plurality of through holes are positioned in the first bottom plate;
a first optical transmission assembly comprising a first end portion positioned in the accommodation space and close to the first photonic die;
a second optical transmission assembly comprising a second end portion positioned in the accommodation space and close to the first photonic die, wherein the first optical transmission assembly and the second optical transmission assembly are configured to send a test light signal to the first photonic die or receive a light output signal generated by the first photonic die;
an interposer disposed on a side of the first bottom plate, wherein the first conductor elements are arranged at intervals and pass through corresponding via holes included in the interposer and the first bottom plate, and are electrically connected between the first photonic die and the first electronic integrated circuit;
a test load board electrically connected to the automatic test equipment; and
a second jig disposed on the test load board and comprising a second base and a plurality of first signal conductors, wherein the second base comprises a second bottom plate, a second side wall, and a groove portion, the groove portion is located between the second side wall and the second bottom plate, the first jig and the second jig are arranged up and down in a direction perpendicular to the test load plate, the first electronic integrated circuit is disposed in the groove portion, and the first signal conductors pass through the second bottom plate and are electrically connected between the first electronic integrated circuit and the test load board.

2. The test device for the optoelectronic integrated circuit before being co-packaged of claim 1, wherein the optoelectronic integrated circuit further comprises a second electronic integrated circuit, the first jig further comprises a plurality of second signal conductors, and the second electronic integrated circuit is arranged on the interposer and located in the accommodation space, wherein the second signal conductors are arranged at intervals and pass through the corresponding through holes of the first bottom plate, and are electrically connected between the interposer and the first electronic integrated circuit.

2. The test device for the optoelectronic integrated circuit before being co-packaged of claim 1, wherein the optoelectronic integrated circuit further comprises a second photonic die, the first jig further comprises a plurality of second conductor elements, and the test device further comprises another first optical transmission assembly and another second optical transmission assembly, wherein the second photonic die is disposed in the accommodation space, the another first optical transmission assembly and the another second optical transmission assemblies are disposed in the accommodation space and close to the second photonic die, respectively, wherein the second conductor elements are arranged at intervals and pass through the corresponding via holes of the interposer and the first bottom plate and are electrically connected between the second photonic die and the first electronic integrated circuit.

3. The test device for the optoelectronic integrated circuit before being co-packaged of claim 3, wherein the first jig further comprises a retaining element disposed on a side of the first side wall or the cover plate, and the first photonic die and/or the second photonic die are fixed on the retaining element and suspended in the accommodation space.

4. The test device for the optoelectronic integrated circuit before being co-packaged of claim 3, wherein the first jig further comprises a first elastic buffer element, which is disposed on a side of the cover plate and pressed against the first photonic die and the second photonic die.

5. The test device for the optoelectronic integrated circuit before being co-packaged of claim 2, wherein the first jig further comprises a first elastic buffer element, which is disposed on a side of the cover plate and pressed against the first photonic die and the second electronic integrated circuit.

6. The test device for the optoelectronic integrated circuit before being co-packaged of claim 1, wherein the first jig further comprises a second elastic buffer element, which is disposed on a side of the interposer and is pressed against the first electronic integrated circuit.

7. The test device for the optoelectronic integrated circuit before being co-packaged of claim 1, further comprising a first connecting member and a second connecting member, and the first connecting member is detachably connected to the second connecting member to connect and fix the first jig and the second jig to the test load board.

8. The test device for the optoelectronic integrated circuit before being co-packaged of claim 2, wherein the first electronic integrated circuit comprises a first packaging structure, and the second electronic integrated circuit comprises a second packaging structure.

9. The test device for the optoelectronic integrated circuit before being co-packaged of claim 1, wherein the first side wall is arranged around the first bottom plate and the accommodation space, and the first optical transmission assembly further comprises a first optical fiber, a first plug, and a first connector, wherein the first connector is disposed on the first side wall, the first optical fiber comprises the first end portion, and the first plug is fixed on the first end portion and pluggably connected to the first connector.

10. The test device for the optoelectronic integrated circuit before being co-packaged of claim 10, wherein the first photonic die comprises a first optical waveguide, the first optical fiber is aligned with the first optical waveguide, and the first end portion is disposed close to the first optical waveguide.

11. The test device for the optoelectronic integrated circuit before being co-packaged of claim 10, wherein the first photonic die comprises a first optical waveguide, and the first connector of the first optical transmission assembly comprises an optical channel and a reflective wall, wherein the reflective wall is located at an acute angle with respect to the first optical fiber and the first photonic die, the test light signal is reflected to the first optical waveguide through the reflective wall, or the light output signal is reflected through the reflective wall to the first end portion.

12. The test device for the optoelectronic integrated circuit before being co-packaged of claim 10, wherein the first photonic die comprises a first optical waveguide, the first connector of the first optical transmission assembly comprises an optical channel, and the cover plate comprises a slot comprising an inclined portion, wherein the inclined portion includes a reflective material with a reflection coefficient greater than that of air and is located at an acute angle with respect to the first optical fiber and the first bottom plate, a part of the first connector is embedded in the slot, and the optical channel extends to the inclined portion, wherein the test light signal is reflected to the first optical waveguide through the inclined portion, or the light output signal is reflected to the first end portion through the inclined portion.

13. The test device for the optoelectronic integrated circuit before being co-packaged of claim 1, wherein the first photonic die comprises a second optical waveguide, and the second optical transmission assembly comprises a second optical fiber, a second plug, and a second connector, wherein the second optical fiber comprises the second end portion, the second connector is obliquely embedded in the cover plate, the second plug is fixed to the second end portion and is pluggably connected to the second connector, and the second end portion is located above the second optical waveguide.

14. The test device for the optoelectronic integrated circuit before being co-packaged of claim 1, further comprising a third optical transmission assembly comprising a third optical fiber, a third plug, a third connector, and an interconnecting optical fiber, wherein the third connector is embedded in the first bottom plate, the third optical fiber comprises a third end portion, the third plug is fixed to the third end portion and is pluggably connected to the third connector, one end of the interconnecting optical fiber is connected to the third connector, and the other end is connected to the first photonic die.
